(19) United States
(12) Patent Application Publication
(10) Pub. No.: US 2005/0285184 A1
(43) Pub. Date: Dec. 29, 2005

(54) Flash memory device and method for programming/erasing the same

(76) Inventor: Jin Hyo Jung, Bucheon-city (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/148,982

(22) Filed: Jun. 9, 2005

(30) Foreign Application Priority Data
Jun. 9, 2004 (KR) 10/2004-0042119

(51) Int. Cl. H01L 29/792

(52) U.S. Cl. 257/324

(57) ABSTRACT

A flash memory device and a method for programming/erasing a flash memory device are disclosed. An example flash memory device includes a semiconductor substrate, an oxide-nitride-oxide (ONO) layer formed on the semiconductor substrate, a blocking insulating layer having a high dielectric constant and being formed on the ONO layer, first conductive poly-gate formed on the blocking insulating layer, and a source/drain area defined by implanting first conductive impurities into the semiconductor substrate positioned at both sides of the first conductive poly-gate.

### RELATED APPLICATION

This application claims the benefit of Korean Patent Application No. 10-2004-0042119, which was filed on Jun. 9, 2004, and which is hereby incorporated herein by reference in its entirety.

### TECHNICAL FIELD

The present disclosure relates to a semiconductor device and, more particularly, to a flash memory device and to a method for programming/erasing a flash memory device having a block nitride layer disposed between a gate and an ONO layer to effectively prevent electrons from being counter-injected into a conduction band of a trap nitride layer during an erasing operation.

### BACKGROUND

Semiconductor memory devices for storing data can be classified as volatile or non-volatile memory devices. Non-volatile memory devices, which include flash memory devices, retain their stored data even if power is interrupted and are thus popular for use in a wide variety of devices such as mobile phone systems and memory cards that may be subject to an unexpected power interruption or that must operate at a low power level.

Generally, cell transistors of the flash memory device have a stacked gate structure. The stacked gate structure includes a gate insulating layer, a floating gate, an inter-gate insulating layer, and a control gate electrode, which are sequentially stacked on a channel area of each cell transistor. If necessary, the flash memory device includes a first silicon layer having a channel area, a first oxide layer for forming a tunneling layer, a nitride layer used as a charge trapping layer, a second oxide layer used as a blocking layer, and a second silicon layer used as a control gate electrode. The above layers constitute a SONOS (polysilicon-oxide-nitride-oxide-silicon) cell structure, and a conventional flash memory device having a SONOS structure is shown in FIG. 1.

As shown in FIG. 1, the conventional SONOS-structured flash memory device acting as an NMOS device includes a P-type substrate (P-well) 10, a tunnel oxide layer 12 formed on a predetermined area of the P-type substrate, a trap nitride layer 13, a block oxide layer 14, and an N+-type polysilicon gate 15. A source/drain 11 in which N+-type impurities are implanted is formed in the substrate 10 corresponding to both sides of the gate 15.

FIG. 2 shows energy levels of individual layers and the movement of electrons and holes when the conventional SONOS-structured flash memory device is erased under an erasing bias condition of a predetermined negative voltage being applied to the gate 15 and the substrate 10 being grounded, such that an electric field is formed between the gate and substrate. With the electric field thus formed, electrons and holes move by a tunneling process. That is, during an erasing operation, holes generated from the P-type substrate 10 tunnel through the tunnel oxide layer 12 and are injected into a valence band of the trap oxide layer 13. In doing so, about 1% of the holes become trapped in a trap level of the trap nitride layer 13, while most (the remaining 99% or so) are delivered to a valance band of the N+-type polysilicon gate 15. Electrons trapped in the trap level of the trap nitride layer 13 before performing the erasing operation are “detrapped” during the erasing operation tunnel through the tunnel oxide layer 12 and are delivered to the P-type substrate 10, thereby reducing a threshold voltage of the SONOS-structured flash memory device.

Performance of the above erasing operation also results in an undesirable flow of electrons, whereby electrons contained in a conduction band of the N+-type polysilicon gate 15 undergo a Fowler-Nordheim (FN) tunneling of the block oxide layer 14 known as back Fowler-Nordheim tunneling such that the electrons are injected into the conduction band of the trap nitride layer 13. Some small portion of the electrons injected into the trap nitride layer 13 by the back FN tunneling become trapped in a trap level of the trap nitride layer 13 to saturate an erasing threshold voltage, but most (about 99%) of the injected electrons tunnel through the tunnel oxide layer 12 to be delivered to the conduction band of the P-type substrate 10. When back FN-tunneled electrons are delivered to the P-type substrate 10 via the tunnel oxide layer 12, excessive FN tunneling stress is applied to the tunnel oxide layer 12 and a trap level is formed between the P-type substrate 10 and the tunnel oxide layer 12 or in the tunnel oxide layer 12, thereby greatly deteriorating an endurance characteristic, which indicates undue variations in a threshold voltage after repeated erasing/programming operations (cycling). Since most back FN-tunneled electrons flow in the P-type substrate 10, there is also a deterioration of a breakdown voltage characteristic and a time-dependent dielectric breakdown (TDDB) characteristic of an ONO (tunnel oxide/trap nitride/block oxide) layer when a negative voltage is applied to the gate compared to when a positive voltage is applied to the gate, such that an erasing voltage of less than a program voltage must be applied to the conventional flash memory device.

Therefore, to erase electrons trapped in the trap nitride layer in the conventional flash memory device as described above, a negative voltage is applied to an N-type poly-gate and a voltage (Vb) higher than the gate voltage (Vg) is applied to the substrate to generate a vertical electric field from the substrate to the gate. Under these conditions, a back FN-tunneling phenomenon occurs, whereby electrons trapped in the trap nitride layer tunnel through the substrate, and at the same time other electrons contained in the gate receiving the negative voltage are counter-injected into the trap nitride layer and the tunnel oxide layer via the block oxide layer. Therefore, most electrons are delivered to the substrate during the erasing operation, but some electrons, about 1%, are left on the trap nitride layer, the tunnel oxide layer, etc., such that an FN stressing is excessively applied to the tunnel oxide layer. As a result, a trap level is formed between the P-type substrate and the tunnel oxide layer or in the tunnel oxide layer, the above-mentioned endurance characteristic deteriorates, and an erasing voltage of less than a program voltage must be applied due to the above-mentioned deterioration of the breakdown voltage characteristic and TDDB characteristic of the ONO layer.

### BRIEF DESCRIPTION OF THE DRAWINGS

FIG. 1 is a cross-sectional view illustrating a conventional SONOS-structured flash memory device.

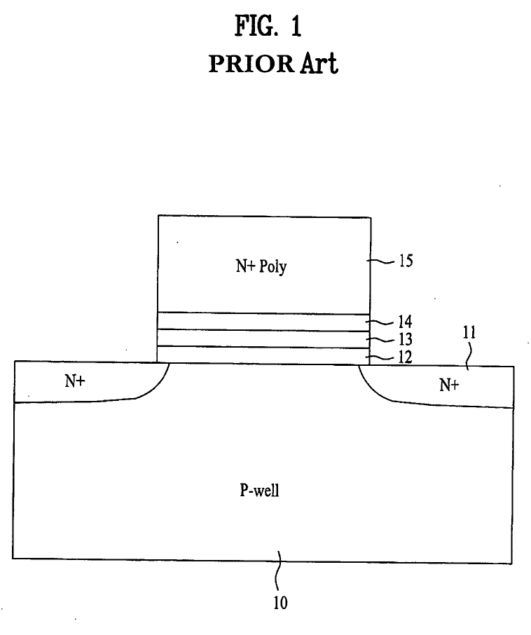

FIG. 2 is a diagram showing energy levels of individual layers and the movement of electrons and holes when erasing the conventional SONOS-structured flash memory device of FIG. 1.

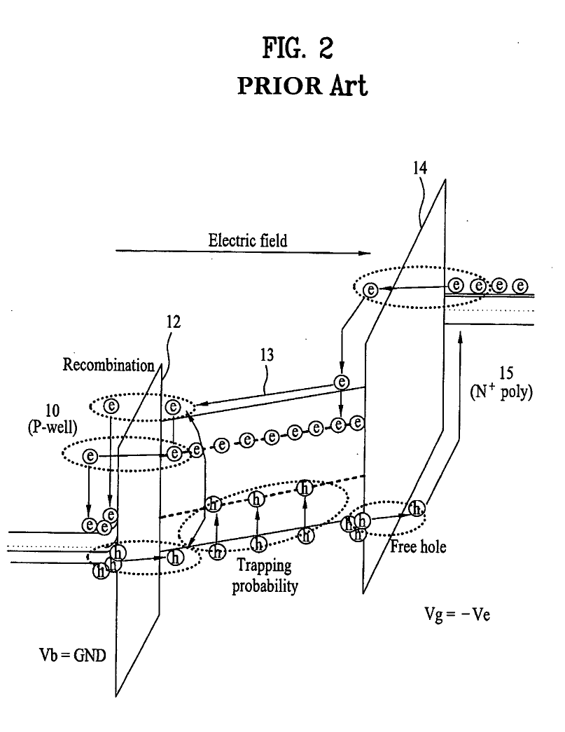

FIG. 3 is a cross-sectional view illustrating an example flash memory device according to the present invention.

FIG. 4 is a diagram showing energy levels of individual layers and the movement of electrons and holes when erasing the example flash memory device of FIG. 3.

FIG. 5 is a diagram showing energy levels of individual layers and the movement of electrons and holes when programming the example flash memory device of FIG. 3.

### DETAILED DESCRIPTION

In general, the example apparatus and methods described herein provide a flash memory device and a method for programming/erasing the same. More specifically, an example flash memory device includes a block nitride layer disposed between a gate and an ONO layer and effectively prevents electrons from being counter-injected into a conduction band of a trap nitride layer during an erasing operation.

An example flash memory device includes a semiconductor substrate, an oxide-nitride-oxide (ONO) layer formed on the semiconductor substrate, a blocking insulating layer having a high dielectric constant and being formed on the ONO layer, a first conductive poly-gate formed on the blocking insulating layer, and a source/drain area defined by implanting first conductive impurities into the semiconductor substrate positioned at both sides of the first conductive poly-gate.

An example method for erasing an example flash memory device includes applying a negative voltage to the poly-gate, grounding the semiconductor substrate, and forming an electric field between the semiconductor substrate and the gate, whereby electrons trapped in the ONO layer are delivered to the drain area, or holes contained in the drain area tunnel the ONO layer.

An example method for programming an example flash memory device applies a positive voltage to the poly-gate, applies a negative voltage to the drain area, and forms a high electric field in an overlapped area between the poly-gate and the drain area, whereby electrons are trapped in the ONO layer, and holes trapped in the ONO layer tunnel through the semiconductor substrate.

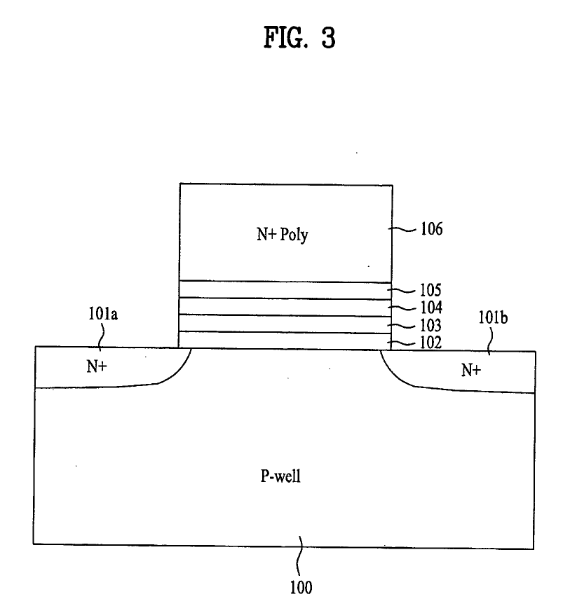

FIG. 3 illustrates an example flash memory device that acts as a SNONOS (polysilicon-nitride-oxide-nitride-oxide-silicon) device. Compared to the conventional SONOS device, the SNONOS-structured flash memory device further includes a block nitride layer 105 disposed between a gate 106 and an ONO layer. The ONO layer is composed of a tunnel oxide layer 102, a trap nitride layer 103, and a block oxide layer 104, which are positioned between the substrate and the gate.

Referring to FIG. 3, the flash memory device includes a P-type substrate (P-well) 100, a tunnel oxide layer 102 formed on a predetermined area of the substrate 100, a trap nitride layer 103, a block oxide layer 104, and a block nitride layer 105, and an N+-type polysilicon gate 106. A source/drain part 101b and 101a, in which N+-type impurities are implanted is formed in the substrate 100 corresponding to both ends of the gate 106. The block nitride layer 105 between the gate 106 and the ONO layer serves to apply a first negative voltage to the gate 106 and a second negative voltage higher than the first negative voltage to the drain 101a formed in the substrate 100, thereby forming an electric field between the drain and gate. In doing so, the block oxide layer 105 blocks electrons generated in the gate 106 from jumping to the trap nitride layer 103 and the tunnel oxide layer 102.

If a negative voltage is applied to the gate 106 during an erasing operation, the block nitride layer 105 acts as a barrier for electrons tunneling through the ONO layer 102˜104. The block nitride layer 105 is formed of a material having a dielectric constant (K) higher than that of the block oxide layer 104. The block nitride layer 105 may also be formed of a material having a high dielectric constant such as, for example, Al₂O₃ or Ta₃O₅.

A thickness of the blocking insulating layer having the high dielectric constant is substituted for the block nitride layer 105 or the same layer is set to a predetermined thickness by which electrons and holes can be normally tunneled between the gate 106 and the substrate 100, when the blocking insulating layer is programmed with the ONO layer. The ONO layer 102˜104, the block nitride layer 105, or the blocking insulating layer substituted for the block nitride layer 105 has a thickness similar to that of the ONO layer of the conventional SONOS-structured flash memory device. For example, if the block nitride layer 105 is formed of a nitride material, the block nitride layer 105 is formed to a thickness of about 10˜100 Å, the block oxide layer 104 is formed to a thickness of about 30 Å, the trap nitride layer 103 is formed to a thickness of about 70˜100 Å, and the tunnel oxide layer 102 is formed to a thickness of about 20 Å. In this case, if the block nitride layer 105 is substituted for the blocking insulating layer formed of Al₂O₃ or Ta₃O₅ having a high dielectric constant, it can adjust a thickness using a dielectric constant of a material of a corresponding blocking insulating layer. For example, if a dielectric constant of the corresponding blocking insulating layer is higher than that of the nitride layer, the blocking insulating layer may be formed to a thickness less than that of the nitride layer. Otherwise, if the blocking insulating layer has a dielectric constant less than that of the nitride layer, the blocking insulating layer may be formed to a thickness higher than that of the nitride layer.

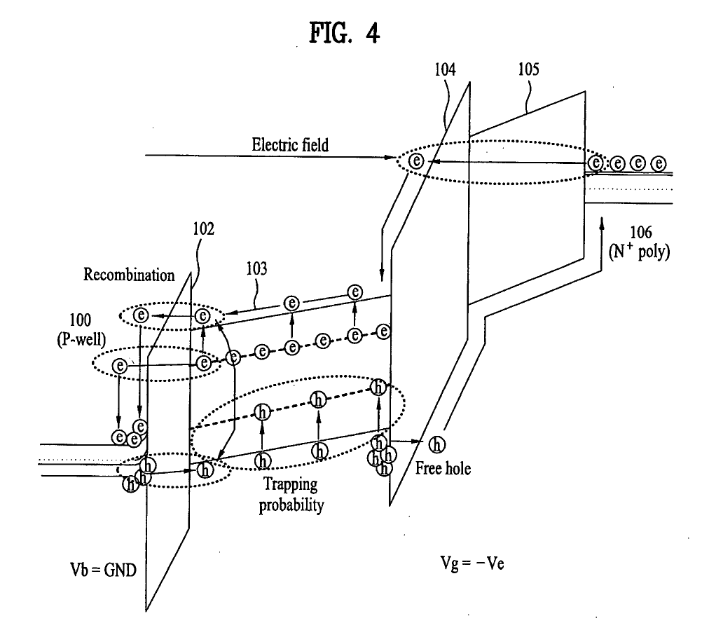

FIG. 4 shows energy levels of individual layers and the movement of electrons and holes when the flash memory device is erased according to the present invention. As shown in FIG. 4, if the flash memory device is erased, a predetermined negative voltage is applied to the N+-type polysilicon gate 106, and a P-type substrate 100 is grounded. In this case, the source 101a or the drain 101b is floated or grounded. Under the aforementioned bias condition, holes generated from the P-type substrate 100 tunnel through the tunnel oxide layer 102 and are injected into a valence band of the trap nitride layer 103. In this case, about 1% of the holes are trapped in a trap level of the trap nitride layer 103, and about 99% of the holes are delivered to a valance band of the N+-type polysilicon gate 106.

Electrons trapped in the trap level of the trap nitride layer 103 before performing the erasing operation are detrapped during the erasing operation, tunnel through the tunnel oxide layer 102, and are delivered to the P-type substrate 100 such that a threshold voltage of the flash memory device is reduced.

In particular, the block nitride layer 105 is additionally deposited on the block oxide layer 104 such that an electron back tunneling length is increased during the erasing operation, thereby exponentially reducing specific phenomenon generated during the erasing operation in the conventional SONOS structure. The specific phenomenon is that other electrons unnecessary for the erasing operation perform FN tunneling of the block oxide layer 104 and enter a conduction band of the trap nitride layer 103.

Therefore, the example flash memory device described herein uses a SNONOS structure to effectively reduce an electron back tunneling current during the erasing operation, and does not encounter saturation of an erasing threshold voltage, resulting in a longer threshold voltage window and higher performance of the flash memory device.

Also, the example flash memory device effectively restricts the FN tunneling stress generated by the electron back tunneling in the tunnel oxide layer 102 such that endurance indicating that a threshold voltage is changed by the erasing/programming operations repeated several times can be effectively improved.

Furthermore, an electron back tunneling current is effectively reduced during the erasing operation in the flash memory device. Therefore, a breakdown voltage characteristic and a TDDB characteristic of the ONO layer 102˜104 when a negative voltage is applied to the gate 106 can be improved to those when a positive voltage is applied to the gate 106, such that an erasing voltage can be increased to a program voltage level.

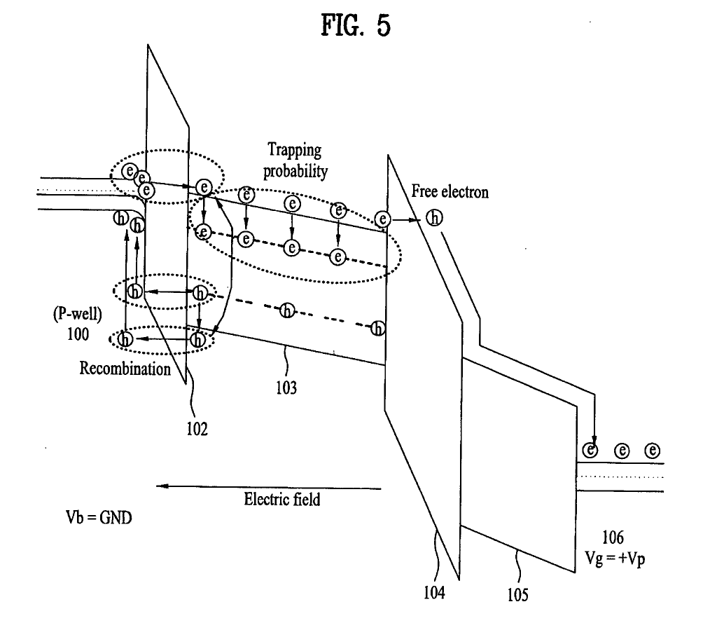

FIG. 5 shows energy levels of individual layers and the movement of electrons and holes when the conventional SONOS-structured flash memory device is programmed using the example method described herein. Referring to FIG. 5, during the program operation in the flash memory device, a predetermined positive voltage (+Vp) is applied to the gate 106, and the substrate 100 (also called a body) is grounded. In this case, the source 101a or the drain 101b is floated or grounded.

Under the above-mentioned bias condition, electrons are trapped in the trap level of the trap nitride layer 103 in the same manner as in the SONOS device, or holes trapped in the trap nitride layer 103 are detrapped and delivered to the silicon substrate 100, and a threshold voltage is increased in such a way that a program operation is carried out.

In this case, electrons untrapped in the trap level of the trap nitride layer 103 from among tunneled electrons tunnel through the block oxide layer 104, and are delivered to the conduction band of the N+-type polysilicon gate 106. In this case, some electrons may be trapped in the trap level of the block nitride layer 105.

However, the block nitride layer 105 is positioned under the N+-type polysilicon gate 106, such that electrons trapped in the trap level of the block nitride layer 105 have little affect upon the threshold voltage, and most electrons trapped in the trap level of the block nitride layer 105 are delivered to the conduction band of the N+-type polysilicon gate 106 within 1 second, such that they are negligible.

As apparent from the above description, the example flash memory device and a method for programming/erasing the same have the following effects. First, the block nitride layer is additionally deposited between the gate and the ONO layer such that an electron back tunneling length is increased during the erasing operation, thereby exponentially reducing the flow of unnecessary electrons (i.e., an electron back FN tunneling current) generated during the erasing operation in the SONOS structure. Second, the flash memory device effectively reduces an electron back tunneling current during the erasing operation such that it does not encounter saturation of an erasing threshold voltage, resulting in a longer threshold voltage window and higher performance of the flash memory device. Third, the flash memory device effectively restricts the FN tunneling stress generated by the electron back tunneling in the tunnel oxide layer such that endurance indicating that a threshold voltage is changed by the erasing/programming operations repeated several times can be effectively improved. Fourth, an electron back tunneling current is effectively reduced during the erasing operation. Therefore, a breakdown voltage characteristic and a TDDB characteristic of the ONO layer when a negative voltage is applied to the gate can be improved to those when a positive voltage is applied to the gate such that an erasing voltage can be increased to a program voltage level.

While the examples herein have been described in detail with reference to example embodiments, it is to be understood that the coverage of this patent is not limited to the disclosed embodiments, but, on the contrary, is intended to cover various modifications and equivalent arrangements included within the sprit and scope of the appended claims.

1. A flash memory device comprising:
a semiconductor substrate;
an oxide-nitride-oxide (ONO) layer formed on the semiconductor substrate;
a blocking insulating layer having a high dielectric constant and being formed on the ONO layer;
a first conductive poly-gate formed on the blocking insulating layer; and
a source/drain area defined by implanting first conductive impurities into the semiconductor substrate positioned at both sides of the first conductive poly-gate.

2. The flash memory device as set forth in claim 1, wherein the blocking insulating layer is formed of one selected from the group consisting of Al₂O₃ and Ta₃O₅.

3. The flash memory device as set forth in claim 1, wherein the blocking insulating layer is a nitride layer.

4. The flash memory device as set forth in claim 3, wherein the nitride layer has a thickness of 10 to 100 Å.

5. The flash memory device as set forth in claim 1, wherein the ONO layer includes a tunnel oxide layer, a trap nitride layer, and a block oxide layer, which are sequentially stacked.

6. A method for erasing a flash memory device which includes a semiconductor substrate; an oxide-nitride-oxide (ONO) layer formed on the semiconductor substrate; a blocking insulating layer formed on the ONO layer; a poly-gate formed on the blocking insulating layer; and a source/drain area defined by implanting impurities into the semiconductor substrate positioned at both sides of the poly-gate, the method comprising:
applying a negative voltage to the poly-gate, grounding the semiconductor substrate, and forming an electric field between the semiconductor substrate and the gate,
whereby electrons trapped in the ONO layer are delivered to the drain area, or holes contained in the drain area tunnel the ONO layer.

7. A method for programming a flash memory device which includes a semiconductor substrate; an oxide-nitride-oxide (ONO) layer formed on the semiconductor substrate; a blocking insulating layer formed on the ONO layer; a poly-gate formed on the blocking insulating layer; and a source/drain area defined by implanting impurities into the semiconductor substrate positioned at both sides of the poly-gate, the method comprising:
applying a positive voltage to the poly-gate, applying a negative voltage to the drain area, and forming a high electric field in an overlapped area between the poly-gate and the drain area,
whereby electrons are trapped in the ONO layer and holes trapped in the ONO layer tunnel through the semiconductor substrate.
